(19) United States
(12) Patent Application Publication
(10) Pub. No.: US 2017/0030949 A1
(43) Pub. Date: Feb. 2, 2017

(54) ELECTRICAL LOAD PREDICTION INCLUDING SPARSE CODING

(71) Applicant: ALCATEL-LUCENT USA INC., Murray Hill, NJ (US)

(72) Inventors: Chun Nam YU, Jersey City, NJ (US); Tin Kam HO, Millburn, NJ (US); Piotr MIROWSKI, London (GB)

(21) Appl. No.: 14/811,989

(22) Filed: Jul. 29, 2015

(51) Int. Cl. G01R 21/00; G01R 21/02

(52) U.S. Cl. CPC G01R 21/00; G01R 21/02

(57) ABSTRACT

A power load prediction method includes determining a relationship between power load and temperature during a selected time. A decomposition of the determined relationship is determined. The decomposition indicates a plurality of contributors to the determined power load. A predicted power load is estimated based on the plurality of contributors and a regression model.

### BACKGROUND

There are various situations in which energy consumption or load prediction would be useful. For example, a utility company may be able to proactively configure grid operation or energy distribution in a manner that accounts for variations in consumer demand if load prediction information were available. Consumers may also be able to configure or tailor their energy usage to account for variations in pricing, for example, by using predictive information regarding their expected energy consumption.

While various attempts have been made to identify the different contributors to energy consumption at a building or enterprise and different approaches to predicting future load conditions exist, there still is a need for a reliable and meaningful predictive model of short term future loads.

### SUMMARY

A power load prediction method includes determining a relationship between power load and temperature during a selected time. A decomposition of the determined relationship is determined. The decomposition indicates a plurality of contributors to the determined power load. A predicted power load is estimated based on the plurality of contributors and a regression model.

A device for predicting power load includes a load analyzer processor and an associated data storage configured to at least temporarily store power load and temperature information. The load analyzer processor uses the power load and temperature information for performing the method of the previous paragraph.

The various features and advantages of this invention will become apparent to those skilled in the art from the following detailed description. The drawings that accompany the detailed description can be briefly described as follows.

### BRIEF DESCRIPTION OF THE DRAWINGS

FIG. 1 schematically represents a system in which energy load information is determined according to an embodiment of this invention.

FIGS. 2A and 2B graphically illustrate example relationships between energy consumption and temperature.

FIG. 3 is a flow chart diagram summarizing an example approach to determining a predictive energy consumption model.

FIGS. 4A-4F graphically illustrate features of a decomposition of load information over time.

### DETAILED DESCRIPTION

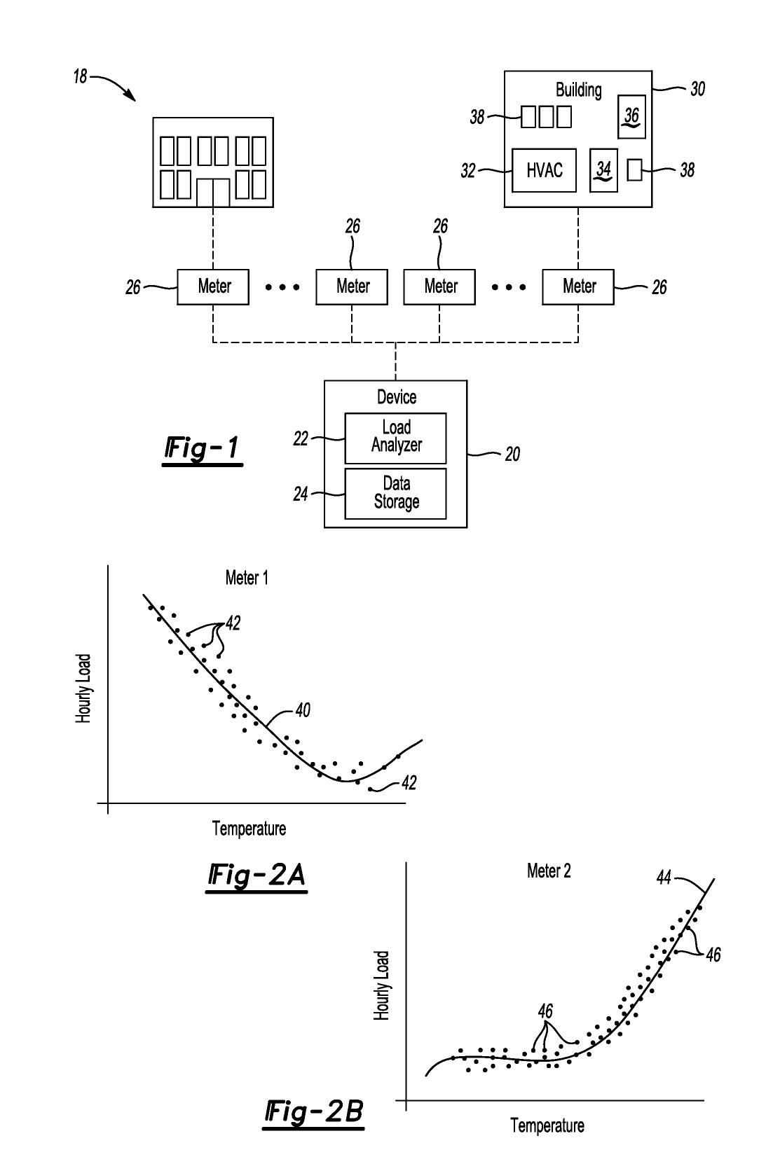

FIG. 1 illustrates a system 18 for utilizing electrical power load information for at least one of a variety of possible purposes. One example use of the power load information is to provide a predictive model to reduce false alarm rates in electricity consumption anomaly detection. Another example use for the information is to assist consumers of electricity in deciding how to respond to dynamic pricing of electricity in smart grid systems.

The illustrated system includes a device 20 configured to make determinations regarding power consumption. The example device 20 includes a load analyzer 22, which comprises at least one computing device or processor. The load analyzer 22 may be realized through various combinations of hardware or electronics and programming or software. The device 20 also includes a data storage 24 associated with the load analyzer 22 in a known manner that allows the load analyzer 22 to obtain stored information or to place information into the data storage. The example data storage 24 comprises at least one physical, hardware component and is used for at least temporarily storing power usage and temperature information. In some examples, the data storage 24 also contains instructions used by the load analyzer 22 for analyzing or otherwise processing power load information.

The load analyzer 22 communicates with a plurality of meter devices 26 that provide an indication of consumed power, such as household consumption of electricity. The meters 26 may be smart meters with known communication capabilities for providing information to the load analyzer 22. Each meter 26 may be dedicated to a particular building or location.

In the illustrated example, one of the meters 26 is associated with a building 30. Only one building (or specific location) is considered for discussion purposes. A variety of power consuming devices are situated within or otherwise associated with the building 30. In FIG. 1, there is a heating, ventilation and cooling (HVAC) unit or system 32, major appliances 34 and 36 (such as a refrigerator), and a plurality of other devices 38 that tend to use less power than the HVAC unit 32 or the major appliances 34 and 36. Given that the HVAC unit 32 tends to use the most power when it operates and the HVAC unit operation is based, at least in part, on ambient temperature conditions in the vicinity of the building 30, the load analyzer 22 utilizes temperature information during power load analysis.

The load analyzer 22 gathers information from each of the meters 26 on a selected basis. For discussion purposes, the load analyzer 22 is assumed to gather load (or power consumption) information on an hourly basis. For example, the load analyzer 22 obtains information from the one meter 26 that indicates how much power was consumed at the associated building 30 every hour during a selected analysis period, which may be a portion of a day, an entire day, a portion of a week, etc. Other monitoring intervals are useful in some situations and those skilled in the art who have the benefit of this description will realize how to control the operation of the load analyzer 22 or communications between the meters 26 and the load analyzer 22 to meet their particular needs.

FIGS. 2A and 2B illustrate possible relationships between temperature and load information. Such information may be gathered by the load analyzer 22 from the corresponding meter 26 and stored in a selected format within the data storage 24. The illustrated example system utilizes actual electricity load data from the individual meters 26. The temperature information may be based on actual measured ambient temperature, inferred temperature information based on nearby measured temperatures or forecasted temperature information. When the load contribution from an HVAC system or device is of interest, ambient temperature information in the vicinity of the building under consideration is relevant as it typically has a direct impact on the operation of the HVAC system or device.

FIG. 2A includes a curve 40 that is a best fit representation of a set of power consumption or measured load indications 42 at different measurement times. The curve 40 represents a relationship between the measured load and ambient temperature. In this example, as temperature increases the load decreases and then begins to increase again. Such a curve may correspond to power consumption at a building 30 over the course of a year, for example. The consumed load is greater at lower temperatures so that building likely includes a system that uses electricity during months when interior heating is desired. The relationship with ambient temperature is a useful characteristic because ambient temperature influences how much heating (or cooling) is needed for the building and heating and cooling is usually the dominant component in household electricity consumption. In FIG. 2A, the lower energy consumption at higher temperatures indicates that electricity-based air conditioning is not often (or perhaps never) used for reducing a temperature in the building 30.

FIG. 2B includes another curve 44, which is a best fit curve for the set of data points 46 that indicate the consumed power at measurement times. The relationship between temperature and load shown in FIG. 2B may represent power consumption in a household over the course of a year or more, for example. Less energy is consumed during the cooler temperatures for this example household likely because gas-based heat rather than electric-based heat is used to maintain desired inside temperatures. The steady increase in electricity usage at higher ambient temperatures corresponds to consuming electricity for air conditioning in the building.

Different buildings or locations will have different patterns or characteristics of energy consumption over time and during different seasons. One feature of the disclosed embodiment is that it provides an ability to use such pattern or characteristic information for isolating particular devices or activities that utilize power in a way that facilitates a more specific and effective predictive model to reduce false alarm rates in electricity consumption anomaly detection or a technique for deciding how to respond to dynamic pricing of electricity in smart grid systems.

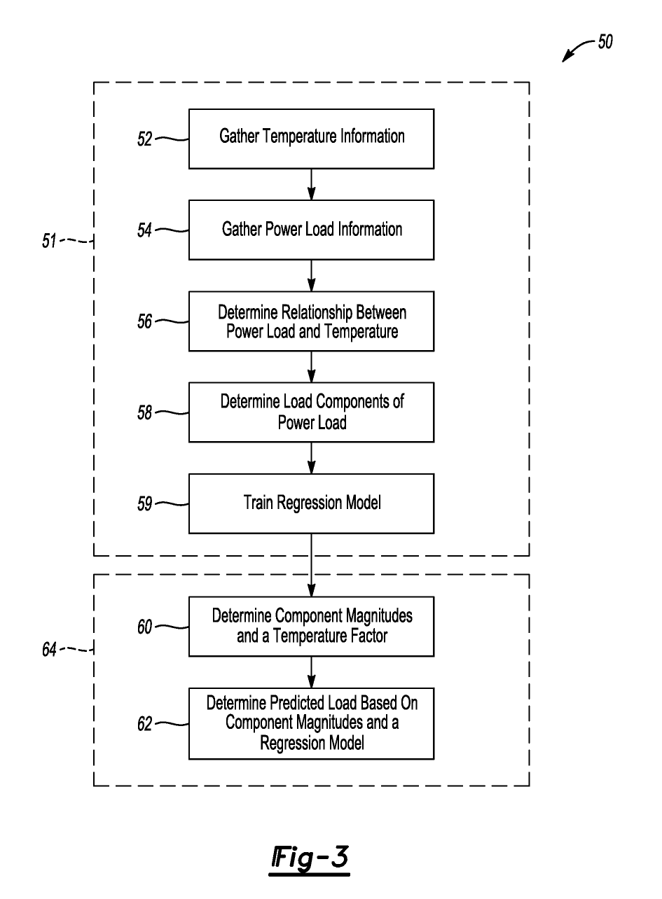

FIG. 3 is a flowchart diagram 50 that summarizes an example approach to providing predictive load information according to an example embodiment. A training or modeling phase is shown at 51. At 52, the load analyzer 22 obtains temperature information. At 54, the load analyzer gathers or obtains power load information from the meter device(s) 26 associated with the building(s) of interest. The steps schematically represented at 52 and 54 may be performed sequentially in the order shown in FIG. 3, simultaneously, or in an opposite order to the illustrated order.

At 56 the load analyzer 22 determines a relationship between temperature and load. As can be appreciated from FIGS. 2A and 2B, the power consumption data points 42, 46 do not fit exactly on the curves 40, 44, respectively. One example embodiment includes using a cubic polynomial-based technique to capture and represent the dependency of load on temperature. This approximation technique works well for individual households in general. The coefficients of a cubic polynomial used in the example technique depend on whether electricity is used for heating and cooling in the house and other factors such as the size of the house.

The load analyzer 22 in this example uses the temperature and load information and performs a least-squares regression of hourly load against a cubic polynomial of the hourly temperature. By way of example, let τ be the temperature, and b(τ) be the corresponding polynomial:

b(τ)=c₃τ³+c₂τ²+c₁τ+c₀

where the coefficients c₃, c₂, c₁, c₀ are estimated using a least squares regression on the hourly load lₖ. The least squares regression used in one example embodiment can be expressed as:

$${min}_{{c}_{0} , {c}_{1} , {c}_{2} , {c}_{3}} {\sum }_{k} {( b ( {τ}_{k} ) - {l}_{k} )}^{2}$$

where (b(τₖ)−lₖ) is the difference between the actual load and the curve at each measured time (e.g., the difference between each data point 42 and the curve 40 in FIG. 2A).

The load analyzer 22 in some embodiments determines such a cubic polynomial fit for each of the households, buildings or locations associated with the respective meters 26.

At 58 in FIG. 3, the load analyzer 22 determines electricity load components based on the relationship determined at 56 through a technique called dictionary learning. Historical data and data regarding the hourly load of a single meter 26 is considered as a vector. The load analyzer 22 determines a decomposition of the hourly load (over a day, or a week, for example) as a sum of the temperature component b(τ) and a few learned load components dⱼ.

The learned, dictionary load components dⱼ, which may be referred to as sparse codes, are obtained in this example embodiment by jointly minimizing reconstruction errors and sparsity over a large set of electricity load signals xᵢ, which can be from the same smart meter 26, or a set of different meters. In this example, the load analyzer 22 uses the following relationship for determining the load components dⱼ.

$${min}_{{d}_{j} , {a}_{ij}} {\sum }_{i - i}^{n} {‖ {x}_{i} - ( {\sum }_{j - i}^{k} {a}_{ij} {d}_{j} + {a}_{Oi} {b}_{i} ( τ ) ) ‖}^{2} + {\sum }_{j - i}^{k} \vert {a}_{ij} \vert$$

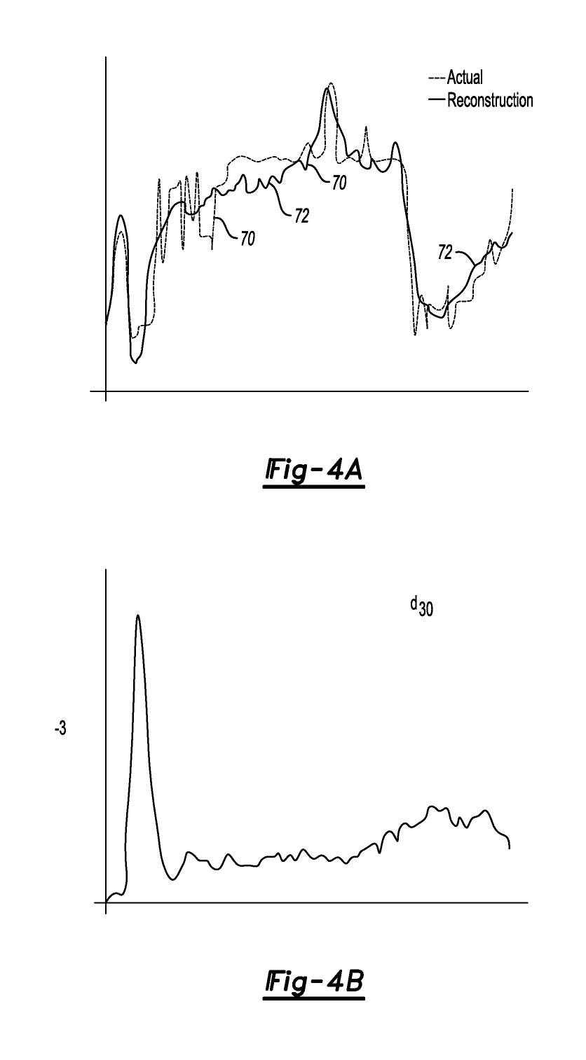

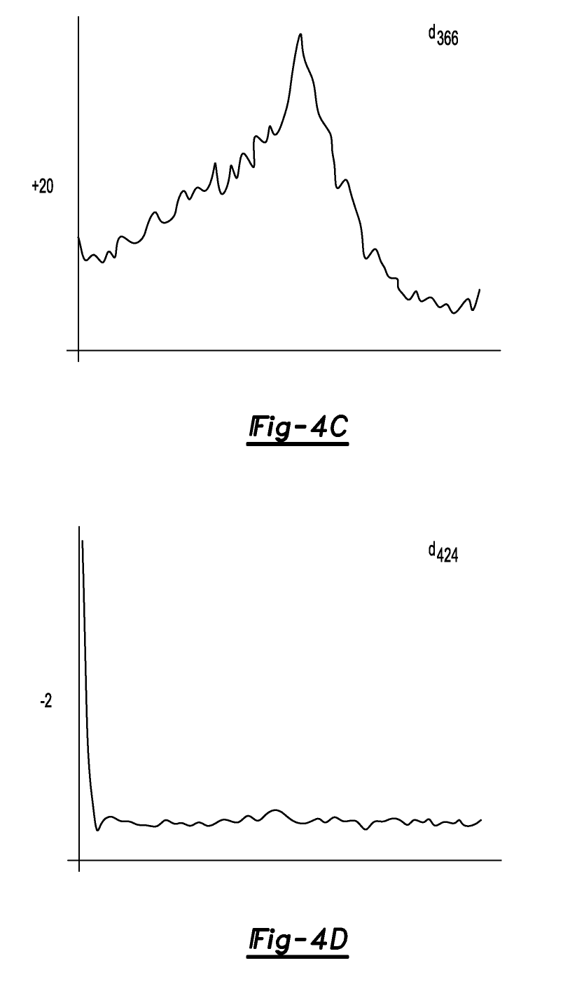

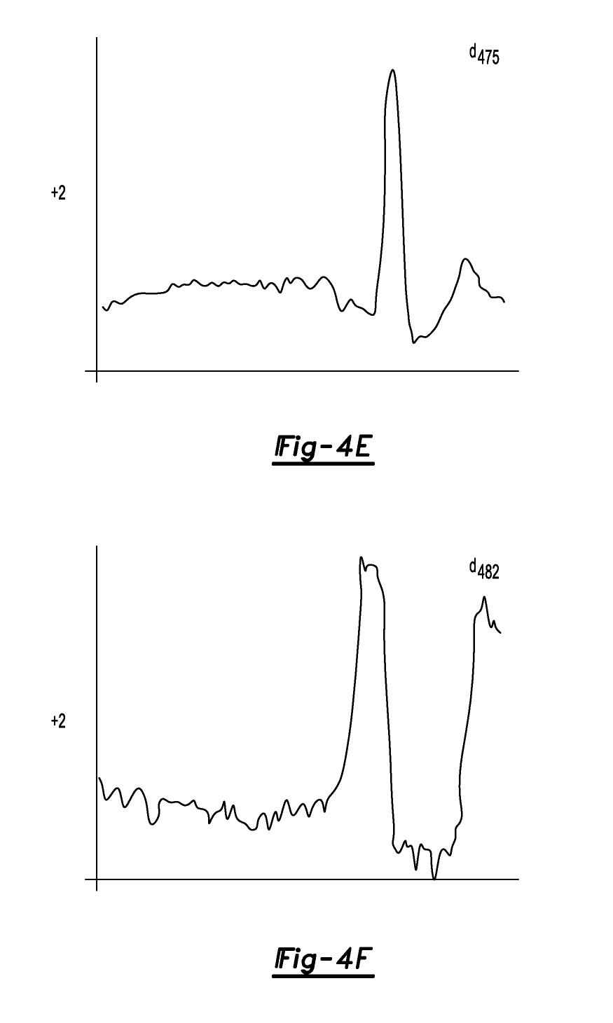

In this example, the index i ranges over the set of input load signals. The first term in the equation minimizes the reconstruction squared error of the signals xᵢ using the dictionary load components dⱼ, while the second term minimizes the sum of absolute values of coefficients aᵢⱼ (l1 minimization). The l1 minimization over coefficients aᵢⱼ shrinks many of these coefficients to zero, so that only a few templates will be used to represent the load signal. The dictionary elements dⱼ are shared across different load signals, while the temperature dependent components bᵢ(τ) are meter-specific. This optimization approach provides the dictionary elements dⱼ, which are related to repeated shapes of the load decomposition curves as shown in FIGS. 4A-4F.

FIG. 4A includes a curve 70 that represents a load over time as reported by a meter 26. FIGS. 4B-4F show decomposition of the load curve 70 into different components that correspond to or represent the values of dⱼ. The individual dictionary elements dⱼ may be interpreted as being attributable to energy consumption by a particular device or for a particular purpose. Repeated shapes or patterns are attributable to repeated activities or energy consuming device operation, for example. Defining or determining an interpretation for the dictionary elements is not a necessary condition to achieving the benefits available from the approach of the example embodiment.

FIG. 4A also includes a curve 72 that represents a reconstruction of the load curve based on the dⱼ curves of FIGS. 4B-4F. As can be appreciated from the illustration, the curve 72 tracks or generally corresponds to the curve 70, which demonstrates that the decomposition is a reasonable estimation of the different components of the load represented by the curve 70.

The sparse codes or dictionary elements dⱼ may be considered factors or template components of a load model that provides for modeling the load contributions from household activities that cannot be explained by heating and cooling. The information based on performing the steps schematically shown at 52-58 is used for regression model training at 59.

The steps schematically shown at 52-59 may be considered a training phase or a model building phase 51 where the dictionary load templates dⱼ and regression model parameters β are estimated from historical data. The steps 52-59 of the model building stage 51 can be done periodically, such as on a weekly or monthly basis, to update the model parameters.

The steps schematically shown at 60-62 can be considered a deployment stage 64 where the estimated dⱼ and regression model parameters fi are used for forecasting (e.g., in a real time setting where load data and temperature data are continuously being collected).

At 60, the load analyzer 22 in this example uses the following relationship and the dictionary elements dⱼ to determine component magnitudes aⱼ and a temperature factor aₒ

$$x = {\sum }_{j = 1}^{k} {a}_{j} {d}_{j} + {a}_{o} b ( τ )$$

Given a set of template components dⱼ and an input signal x, this decomposition can be done using algorithms, such as a known basis pursuit technique, by solving

min_{aⱼ}½|x−(Σⱼ₌₁^{k}aᵢⱼdⱼ)|²+Σⱼ|aⱼ|

The coefficients or component magnitudes aⱼ obtained in the decomposition indicate how much each of the template components dⱼ contribute to the total load over the time under consideration, such as the past week. These coefficients aⱼ are then used as input features at 62 in a regression algorithm or model to predict the future electricity load. The regression algorithm in some example embodiments is a known regression algorithm such as support vector regression or ridge regression.

One example embodiment includes the regression model:

y=f(x,τ,a;β)

where y is the target load such as next-day or next-week total load of a household, x is the historical load of that household over a selected time period (e.g., the previous week, month, etc.), and t is the temperature/temperature forecast data. The vector a is the decomposition using load templates dⱼ into magnitudes aⱼ. β is the regression parameter for the regression model f. This regression model differs from others that do not include any load decomposition information. Including the magnitude of the load contribution aᵢⱼ from each of the dictionary load templates dⱼ provides better load prediction capabilities.

One example embodiment includes building a regression model to predict the next day total load using a collected sequence of daily load values l₁, l₂, . . . lₙ for n days together with next-day average daily temperature forecasts τ₁, τ₂, . . . τₙ.

In a linear regression model, regression coefficients \vec{β} can be estimated using the relationship:

γ=\vec{β}·\vec{χ}+ε,

where γ is the target variable, \vec{χ} is the set of features/covariates used to predict the target, and ε is usually assumed t be some zero-meaned Gaussian noise.

One example feature vector \vec{χ} is based upon the total load of the previous seven days and the average temperature forecast for the next day as input features. There are eight features, so the parameter vector \vec{β} is also 8-dimensional in this example. Intuitively this corresponds to the next-day load being a linear function of the previous seven day load and the next-day average temperature forecast, with the dependence captured by the parameter vector \vec{β}. In this case, for γ=lₜ,

\vec{x}=[lₜ₋₁lₜ₋₂lₜ₋₃lₜ₋₄lₜ₋₅lₜ₋₆lₜ₋₇τₜ].

Since t can range from 8 (start with 8 because this example includes the previous seven days for \vec{χ}) up to n, there are many such (\vec{χ}, y) pairs for estimating the parameter vector \vec{β}. One method for performing estimation is to use least-square estimation:

$${min}_{\vec{β}} {\sum }_{i} {( \vec{β} \cdot {\vec{x}}_{i} - {y}_{i} )}^{2}$$

for all such pairs (\vec{χ}ᵢ, yi).

In the case of using sparse code features, the features space is enriched with coefficients αⱼ obtained from sparse code decompositions. If there are k sparse codes d in the dictionary, the original feature vector \vec{χ} is augmented with k more features, and the feature vector becomes:

\vec{x}=[lₜ₋₁lₜ₋₂lₜ₋₃lₜ₋₄lₜ₋₅lₜ₋₆lₜ₋₇τₜα₁α₂ . . . αₖ].

The parameter vector \vec{β} will correspondingly have more parameters, but the estimation procedure remains the same (for example, with least squares estimation).

The predicted load information available from embodiments of this invention may be useful to assist a consumer of power in adjusting power usage based on varying pricing intervals. The predicted load information may be useful to a supplier of power to anticipate or evaluate dynamic changes in power delivery or consumption in a manner that avoids false alarms during anomaly detection.

The preceding description is illustrative rather than limiting. Variations and modifications to the disclosed example embodiment may become apparent to those skilled in the art and such changes do not necessarily depart from the essence of this invention. The scope of legal protection afforded this invention can only be determined by studying the following claims.

We claim:

1. A method, comprising the steps of:
determining a relationship between power load and temperature during a selected time;
determining a decomposition of the determined relationship, wherein the decomposition indicates a plurality of contributors to the determined power load; and
estimating a predicted power load based on the plurality of contributors and a regression model.

2. The method of claim 1, comprising
determining a magnitude for at least some of the contributors; and
estimating the predicted power load based on the determined magnitudes.

3. The method of claim 2, comprising using the determined magnitudes as inputs to the regression model.

4. The method of claim 1, wherein determining the decomposition comprises using a dictionary learning technique to determine the plurality of contributors.

5. The method of claim 4, comprising determining the contributors based on minimizing reconstruction errors and sparsity over a plurality of load signals.

6. The method of claim 1, wherein the regression model comprises at least one of a support regression algorithm or a ridge regression algorithm.

7. The method of claim 1, comprising
determining the temperature based on at least one of a measured temperature over time or an estimated temperature over time.

8. The method of claim 7, wherein the temperature comprises an ambient temperature in a vicinity of where the power of the power load is consumed.

9. The method of claim 1, wherein determining the relationship between temperature and power load comprises
obtaining a plurality of load indications at selected times and corresponding temperature indications at the selected times;
determining a cubic polynomial of the temperature indications; and
performing an least squares regression of the load indications against the cubic polynomial.

10. A device, comprising:
a load analyzer processor and an associated data storage configured to at least temporarily store power load and temperature information, the load analyzer processor using the power load and temperature information for
determining a relationship between power load and temperature during a selected time;
determining a decomposition of the determined relationship, wherein the decomposition indicates a plurality of contributors to the determined power load; and
estimating a predicted power load based on the plurality of contributors and a regression model.

11. The device of claim 10, wherein the processor is configured to
determine a magnitude for at least some of the contributors; and
estimate the predicted power load based on the determined magnitudes.

12. The device of claim 11, wherein the processor is configured to use the determined magnitudes as inputs to the regression model.

13. The device of claim 10, wherein the processor is configured to determine the decomposition using a dictionary learning technique to determine the plurality of contributors.

14. The device of claim 13, wherein the processor is configured to determine the contributors based on minimizing reconstruction errors and sparsity over a plurality of load signals.

15. The device of claim 10, wherein the regression model comprises at least one of a support regression algorithm or a ridge regression algorithm.

16. The device of claim 10, wherein the processor is configured to
determine the temperature based on at least one of a measured temperature over time or an estimated temperature over time.

17. The device of claim 16, wherein the temperature comprises an ambient temperature in a vicinity of where the power of the power load is consumed.

18. The device of claim 10, wherein the processor is configured to determine the relationship between temperature and power load by
obtaining a plurality of load indications at selected times and corresponding temperature indications at the selected times;
determining a cubic polynomial of the temperature indications; and
performing an least squares regression of the load indications against the cubic polynomial.
